(19) United States
(12) Patent Application Publication
(10) Pub. No.: US 2019/0065081 A1
(43) Pub. Date: Feb. 28, 2019

(54) DISK DEVICE AND DATA PARALLEL PROCESSING METHOD

(71) Applicants: Kabushiki Kaisha Toshiba, Tokyo (JP); Toshiba Electronic Devices & Storage Corporation, Tokyo (JP)

(72) Inventors: Yoshihiko Takeda, Kawasaki Kanagawa (JP); Tomonari Tashiro, Yokohama Kanagawa (JP)

(21) Appl. No.: 15/919,421

(22) Filed: Mar. 13, 2018

(30) Foreign Application Priority Data
Aug. 30, 2017 (JP) 2017-165642

(51) Int. Cl. G06F 3/06; G06F 12/0868; G06F 12/02; G11C 16/10; G06F 13/16; G06F 1/30

(52) U.S. Cl. CPC G06F 3/0619; G06F 12/0868; G06F 1/30; G11C 16/105; G06F 13/1694; G06F 12/0246

(57) ABSTRACT

According to one embodiment, a disk device includes a disk, a plurality of flash ROMs, a head, a cache memory, and a controller. The controller is configured to execute an operation when supply of power from an external power supply is interrupted while writing of data into the disk is performed by using power supplied from the external power supply, wherein the operation includes writing data stored in the cache memory into the flash ROMs in order, by means of serial communication, by using power supplied from an auxiliary power supply. Here, the controller writes data into a first flash ROM of the plurality of flash ROMs, and, in parallel therewith, reads data from a second flash ROM of the plurality of flash ROMs where writing of data is not performed, by means of serial communication.

### CROSS-REFERENCE TO RELATED APPLICATIONS

This application is based upon and claims the benefit of priority from Japanese Patent Application No. 2017-165642, filed on Aug. 30, 2017; the entire contents of which are incorporated herein by reference.

### FIELD

Embodiments described herein relate generally to a disk device and a data parallel processing method.

### BACKGROUND

Disk devices provide a Power Loss Protection (PLP) function that saves data, which is stored in a cache memory and is under writing into a disk, into a plurality of flash Read Only Memories (ROMs) when supply of power from an external power supply is interrupted. Specifically, a disk device achieves the PLP function by selecting one flash ROM from the plurality of flash ROMs in order, and repeating writing of data into these flash ROMs and reading of data from these flash ROMs.

However, when the PLP function is used to save data stored in the cache memory into the plurality of flash ROMs, it is not possible to simultaneously perform writing of data into a flash ROM and reading of data from a flash ROM. Thus, it takes a long time for the PLP function to write the data into the flash ROMs.

An object of one embodiment is to provide a disk device that can shorten the processing time necessary for executing the PLP function and can increase the data storage amount into the flash ROMs.

### BRIEF DESCRIPTION OF THE DRAWINGS

FIG. 1 is a block diagram illustrating a configuration example of a disk device according to a first embodiment;

FIG. 2 is a diagram illustrating an example of timing charts of chip selection signals transmitted by chip selection signal lines in the disk device according to the first embodiment;

FIG. 3 is a diagram illustrating an example of timing charts of various signals transmitted by an input signal line and an output signal line in the disk device according to the first embodiment;

FIG. 4 is a diagram illustrating an example of timing charts of input and output of various signals in respective flash ROMs in the disk device according to the first embodiment;

FIG. 5 is a block diagram illustrating a configuration example of a disk device according to a second embodiment; and

FIG. 6 is a diagram illustrating a configuration example of a bus fight preventing circuit included in the disk device according to the second embodiment.

### DETAILED DESCRIPTION

In general, according to one embodiment, a disk device includes a disk, a plurality of flash ROMs, a head, a cache memory, and a controller. The head is configured to perform writing and reading of data into and from the disk. The cache memory is configured to store data under writing into the disk. The controller is configured to execute an operation when supply of power from an external power supply is interrupted while writing of data into the disk is performed by using power supplied from the external power supply, wherein the operation includes writing data stored in the cache memory into the flash ROMs in order, by means of serial communication, by using power supplied from an auxiliary power supply. Here, the controller writes data into a first flash ROM of the plurality of flash ROMs, and, in parallel therewith, reads data from a second flash ROM of the plurality of flash ROMs where writing of data is not performed, by means of serial communication.

Exemplary embodiments of a disk device and a data parallel processing method will be explained below in detail with reference to the accompanying drawings. The present invention is not limited to the following embodiments. In the present embodiment, although the disk device includes the disk, the disk device may include a plurality of the disks. In addition, in the present embodiment, although the disk device includes the head, the disk device may include a plurality of the heads.

### First Embodiment

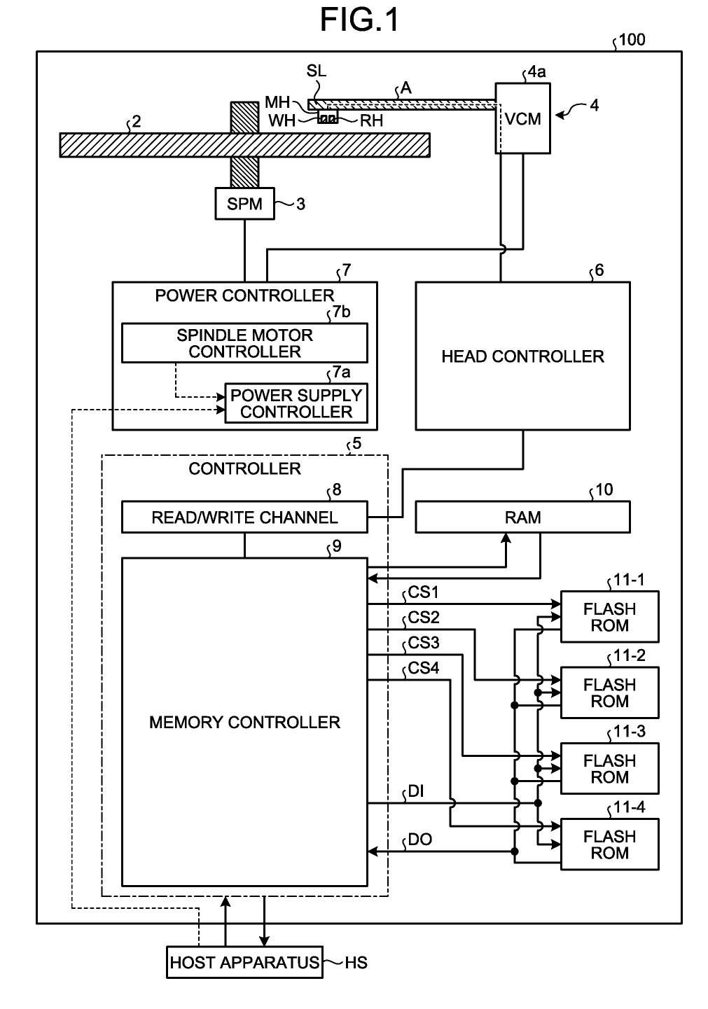

FIG. 1 is a block diagram illustrating a configuration example of a disk device according to a first embodiment. For example, the disk device 100 is a hard disk drive, and serves as an external storage device of a host apparatus HS. Specifically, the disk device 100 includes a disk 2, a spindle motor (SPM) 3, a magnetic head MH, an actuator arm A, a voice coil motor (VCM) 4, a controller 5, a head controller 6, a power controller 7, a Random Access Memory (RAM) 10, and a plurality of flash Read Only Memories (ROMs) 11-1, 11-2, 11-3, and 11-4 (which will be referred to as “flash ROMs 11”, hereinafter, when the flash ROMs 11-1, 11-2, 11-3, and 11-4 do not need to be distinguished from each other).

The disk 2 is a disk-shaped recording medium (such as a magnetic disk) that can record various information, and can be rotationally driven by the SPM 3. The magnetic head MH is provided at one end of the actuator arm A, to execute writing and reading of data into and from the disk 2. The magnetic head MH includes a write head WH for writing data into the disk 2, and a read head RH for reading data from the disk 2. The magnetic head MH is supported on a slider SL, and can move in a down-track direction above the surface of the disk 2, while maintaining a state slightly levitated from the surface of the disk 2 by a lifting force generated by rotation of the disk 2.

The VCM 4 is provided at the other end of the actuator arm A opposite to the end provided with the magnetic head MH, to rotationally drive the actuator arm A about an axis 4a as the center. With this operation, the VCM 4 can move the magnetic head MH in a cross-track direction, to change tracks for writing or reading data on the disk 2.

The power controller 7 controls supply of power to the disk device 100. Further, the power controller 7 controls drive of the VCM 4. The power controller 7 includes a power supply controller 7a and a spindle motor controller 7b. The spindle motor controller 7b controls rotation of the SPM 3. Upon receiving power supplied from the host apparatus HS (an example of the external power supply), the power supply controller 7a supplies the power thus supplied, to the respective parts of the disk device 100. Further, the power supply controller 7a can detect that the supply of power from the host apparatus HS is interrupted. In this embodiment, the power supply controller 7a detects that the supply of power from the host apparatus HS is interrupted, even when the power supplied from the host apparatus HS is lowered to a level with which the disk device 100 cannot keep operating.

Further, when detecting that the supply of power from the host apparatus HS is interrupted, the power supply controller 7a informs the controller 5 that the supply of power from the host apparatus HS is interrupted, and receives a counter electromotive force generated by rotation of the SPM 3, via the spindle motor controller 7b. Then, the power supply controller 7a supplies the counter electromotive force received from the SPM 3, to the respective parts of the disk device 100, as power supplied from an auxiliary power supply. Where the disk device 100 includes a power storage function part, such as a battery or capacitor, the power supply controller 7a can use this power storage function part to serve as an auxiliary power supply, in addition to the counter electromotive force received from the SPM 3 or in place of the counter electromotive force received from the SPM 3.

The controller 5 includes a read/write channel 8 and a memory controller 9. The read/write channel 8 writes data into the disk 2, while controlling the write head WH by the head controller 6. Further, the read/write channel 8 reads data from the disk 2, while controlling the read head RH by the head controller 6.

The memory controller 9 is composed of a Central Processing Unit (CPU), a logic circuit, and so forth, and conducts overall control on the disk device 100 in accordance with commands received from the host apparatus HS. In this embodiment, the memory controller 9 achieves a Power Loss Protection (PLP) function. The PLP function is a function that saves data under writing (data stored in the RAM 10 described later) into the flash ROMs 11 to prevent loss of the data when it is detected that the supply of power from the host apparatus HS is interrupted while writing of the data into disk 2 is performed.

The RAM 10 is composed of a Dynamic Random Access Memory (DRAM), Static Random Access Memory (SRAM), or the like, and serves as an example of a cache memory for temporarily storing data under writing into the disk 2. The flash ROMs 11 serve as a storage part into which data stored in the RAM 10 is saved, when the PLP function is executed.

Next, an explanation will be given of the PLP function achieved in the disk device 100 according to this embodiment, with reference to FIG. 1. The memory controller 9 has a configuration that can perform serial communication with the plurality of flash ROMs 11 via an input signal line DI for input that can transmit data to be written into the flash ROMs 11 and an output signal line DO for output that can transmit data read from the flash ROMs 11. Further, the memory controller 9 is connected to the respective flash ROMs 11 via chip selection signal lines CS1, CS2, CS3, and CS4 (which will be referred to as “chip selection signal lines CS”, hereinafter, when the chip selection signal lines CS1, CS2, CS3, and CS4 do not need to be distinguished from each other), each of which transmits a chip selection signal for selecting one of the flash ROMs 11 to write data or read data.

Further, when writing data into the disk 2, the memory controller 9 stores, into the RAM 10, the data to be written into the disk 2. By using power supplied from the host apparatus HS, the read/write channel 8 writes data stored in the RAM 10 into the disk 2 via the head controller 6.

Then, when the power supply controller 7a detects that the supply of power from the host apparatus HS is interrupted while writing of the data into the disk 2 is performed, the memory controller 9 executes the PLP function. Specifically, by using power supplied from the auxiliary power supply, the memory controller 9 writes data stored in the RAM 10 into the plurality of flash ROMs 11 in order via the input signal line DI, by means of serial communication. Here, it is assumed that this serial communication means to write data into the plurality of flash ROMs 11 via the single input signal line DI. Further, in parallel with writing of data into one flash ROM 11 of the plurality of flash ROMs 11 (for example, the flash ROM 11-2), the memory controller 9 reads data from another flash ROM 11 of the plurality of flash ROMs 11, which is other than the flash ROM 11-2 (in other words, a flash ROM 11, such as the flash ROM 11-1, where writing of data is not being performed), via the output signal line DO, by means of serial communication. Here, it is assumed that this serial communication means to read data from the flash ROMs 11 via the single output signal line DO.

Consequently, when the disk device 100 including the plurality of flash ROMs 11 executes the PLP function, it is possible to efficiently perform writing and reading of data into and from the flash ROMs 11. Thus, it is possible to shorten the processing time necessary for executing the PLP function, and to increase the data storage amount into the flash ROMs 11.

For example, in the disk device 100 according to this embodiment, where the Page Program Time (tPP) of each flash ROM 11 is assumed to be 500 μsec, which is after a command for instructing execution of the PLP function is issued when the supply of power from the host apparatus HS is interrupted, it is possible to shorten the processing time necessary for executing the PLP function, by 10% or more, and to increase the data storage amount. Here, the tPP denotes the time necessary for writing data into each flash ROM 11. Further, if a flash ROM 11 having a shorter tPP is developed in future, and/or the number of flash ROMs 11 connected to the memory controller 9 is increased, it is possible to shorten the processing time necessary for executing the PLP function, by up to about 50% at maximum.

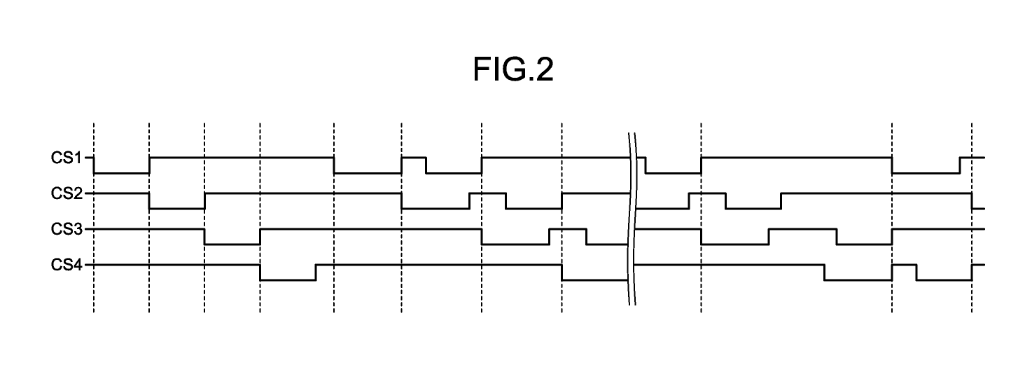

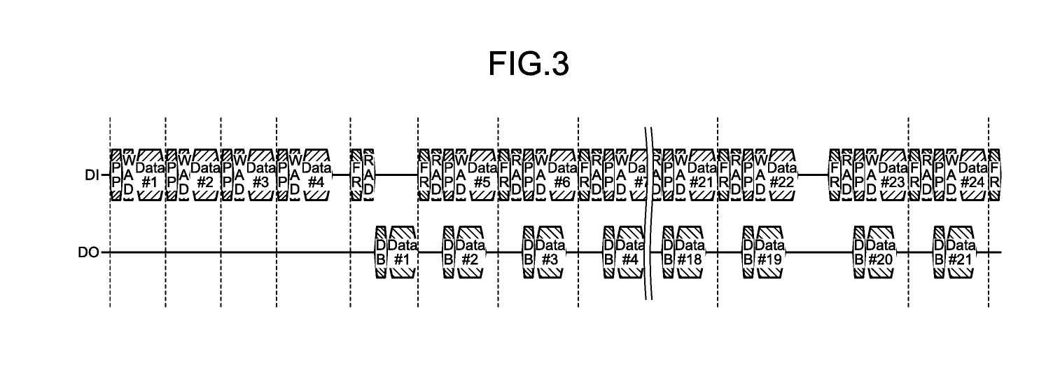

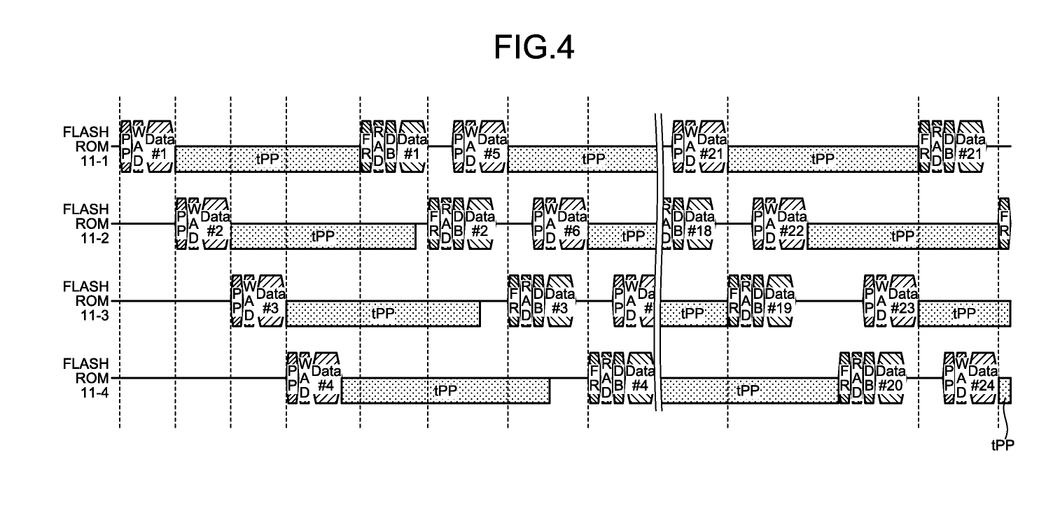

Next, an explanation will be given of an execution example of the PLP function in the disk device 100 according to this embodiment, with reference to FIGS. 2 to 4. FIG. 2 is a diagram illustrating an example of timing charts of chip selection signals transmitted by the chip selection signal lines in the disk device according to the first embodiment. FIG. 3 is a diagram illustrating an example of timing charts of various signals transmitted by the input signal line and the output signal line in the disk device according to the first embodiment. FIG. 4 is a diagram illustrating an example of timing charts of input and output of various signals in the respective flash ROMs in the disk device according to the first embodiment.

When the power supply controller 7a detects that the supply of power from the host apparatus HS is interrupted while writing of data into disk 2 is performed, the memory controller 9 asserts chip selection signals to be output into the respective chip selection signal lines CS, in the order of the chip selection signal line CS1, the chip selection signal line CS2, the chip selection signal line CS3, and the chip selection signal line CS4, as illustrated in FIG. 2. In this embodiment, the chip selection signals are assumed to be negative logic. However, the chip selection signals are not limited to this example, but may be positive logic. Consequently, the memory controller 9 sets the flash ROM 11-1, the flash ROM 11-2, the flash ROM 11-3, and the flash ROM 11-4, in this order, in a state into which data can be written.

Further, as illustrated in FIG. 2, the memory controller 9 asserts chip selection signals to be output into the respective chip selection signal lines CS connected to the flash ROMs 11, in the order of the flash ROMs 11 in earliness for when the tPP has elapsed after each of the flash ROMs 11 was set in a state into which data can be written. Consequently, the memory controller 9 sets the flash ROM 11-1, the flash ROM 11-2, the flash ROM 11-3, and the flash ROM 11-4, in this order, in a state from which data can be read. Further, as illustrated in FIG. 2, the memory controller 9 asserts chip selection signals to be output into the respective chip selection signal lines CS connected to the flash ROMs 11, again, in the order of the flash ROMs 11 in earliness for when reading of data has been completed. Consequently, the memory controller 9 sets the flash ROM 11-1, the flash ROM 11-2, the flash ROM 11-3, and the flash ROM 11-4, in this order, in a state into which data can be written, again.

Further, as illustrated in FIGS. 3 and 4, the memory controller 9 inputs a PP signal, a WAD signal, and Data #n, which is data stored in the RAM 10, into the flash ROMs 11 via the input signal line DI, in the order of the flash ROMs 11 in earliness for when a chip selection signal has been asserted thereto. Here, the PP signal is a command for instructing writing of data into a flash ROM 11. The WAD signal is a signal indicating the address of a storage area in a flash ROM 11 to write data therein. Consequently, as illustrated in FIGS. 3 and 4, the memory controller 9 writes Data #1, Data #2, Data #3, and Data #4, which are data stored in the RAM 10, into the flash ROM 11-1, the flash ROM 11-2, the flash ROM 11-3, and the flash ROM 11-4, in this order.

Then, as illustrated in FIGS. 3 and 4, after outputting data into the flash ROMs 11, the memory controller 9 inputs an FR signal and a RAD signal into the flash ROMs 11 via the input signal line DI, and reads data from the flash ROMs 11, in the order of the flash ROMs 11 in earliness for when the tPP has elapsed and a chip selection signal has been asserted thereto. Consequently, as illustrated in FIGS. 3 and 4, the memory controller 9 reads data (Data #1, Data #2, Data #3, and Data #4) from the flash ROM 11-1, the flash ROM 11-2, the flash ROM 11-3, and the flash ROM 11-4, in this order.

Here, the FR signal is a command for instructing reading of data from a flash ROM 11. The RAD signal is a signal indicating the address of a storage area in a flash ROM 11 to read data therefrom. In this embodiment, it is assumed that, prior to reading of data from a flash ROM 11, the memory controller 9 reads a dummy bite DB from the flash ROM 11 via the output signal line DO.

Further, in this embodiment, it is assumed that the memory controller 9 reads data from a flash ROM 11 and then executes verify-read for comparing the data read from this flash ROM 11 with the data written into this flash ROM 11. Then, when the data read from this flash ROM 11 differs from the data written into this flash ROM 11, the memory controller 9 detects an abnormality of writing of data in this flash ROM 11.

Further, as illustrated in FIGS. 3 and 4, after finishing the reading of data, the memory controller 9 inputs the PP signal, the WAD signal, and Data #n, which is data stored in the RAM 10, into the flash ROMs 11 via the input signal line DI, in the order of the flash ROMs 11 in earliness for when a chip selection signal has been asserted thereto. Consequently, as illustrated in FIGS. 3 and 4, the memory controller 9 writes Data #5, Data #6, Data #7, and Data #8, which are data stored in the RAM 10, into the flash ROM 11-1, the flash ROM 11-2, the flash ROM 11-3, and the flash ROM 11-4, in this order.

As illustrated in FIGS. 3 and 4, after finishing the first round writing of data into the flash ROMs 11-1, 11-2, 11-3, and 11-4 as a result of the processes described above, the memory controller 9 repeats writing and reading of data into and from the flash ROMs 11, in the order of reading of Data #n, reading of Data #n+1, writing of Data#n+m, reading of Data #n+2, and writing of Data #n+m+1. Here, “m” denotes the number of flash ROMs 11 (four, in this embodiment). Consequently, in parallel with writing of data (for example, the Data #5) into a flash ROM 11 (for example, the flash ROM 11-1) where reading of data has been finished, the memory controller 9 performs reading of data (for example, the Data #2) from another flash ROM 11 (for example, the flash ROM 11-2), by means of serial communication.

Further, the memory controller 9 consecutively outputs a command about reading of data from one flash ROM 11 (for example, the FR signal and WAD signal to be input into the flash ROM 11-2) and a command about writing of data into another flash ROM 11 (for example, the PP signal and RAD signal to be input into the flash ROM 11-1), by serial communication. Consequently, it is possible to efficiently use the input signal line DI, which transmits commands about writing and reading of data into and from the flash ROMs 11. In this embodiment, the memory controller 9 outputs a command about reading of data from one flash ROM 11, and then, when there comes a state (Don't care) where a signal transmitted through the input signal line DI is not defined, the memory controller 9 outputs a command about writing of data into another flash ROM 11.

As described above, according to the first embodiment, when the supply of power from the host apparatus HS is interrupted while writing of the data into disk 2 is performed, power supplied from the auxiliary power supply is used, and data stored in the RAM 10 is written into the plurality of flash ROMs 11 in order via the input signal line DI, by means of serial communication. Here, writing of data into one flash ROM 11 of the plurality of flash ROMs 11 is performed, and, in parallel therewith, reading of data from another flash ROM 11 of the plurality of flash ROMs 11, where the writing of data is not performed, is performed via the output signal line DO, by means of serial communication. As a result, when the disk device 100 including the plurality of flash ROMs 11 executes the PLP function, it is possible to efficiently perform writing and reading of data into and from the flash ROMs 11. Thus, an effect can be obtained to shorten the processing time necessary for executing the PLP function, and to increase the data storage amount into the flash ROMs 11.

### Second Embodiment

This embodiment relates to an example including a circuit for preventing a bus fight that means a state where, while writing of data into one flash ROM is performed, the output from another flash ROM, from which reading of data is performed in parallel with the writing of data into one flash ROM, comes to be fixed to a high level or low level. In the following description, no explanation will be given of the same constituent elements as those in the first embodiment.

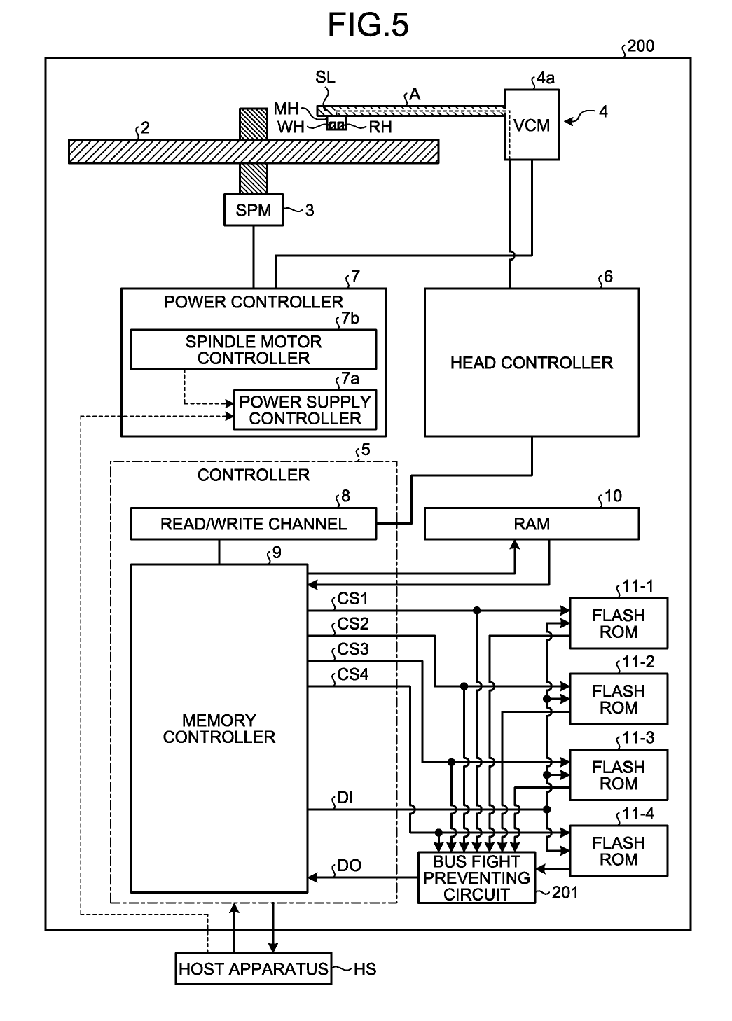

FIG. 5 is a block diagram illustrating a configuration example of a disk device according to the second embodiment. As illustrated in FIG. 5, the disk device 200 includes the disk 2, the spindle motor 3, the magnetic head MH, the actuator arm A, the voice coil motor 4, the controller 5, the head controller 6, the power controller 7, the RAM 10, the plurality of flash ROMs 11, and a bus fight preventing circuit 201.

The bus fight preventing circuit 201 is a circuit for preventing a bus fight where, while data is being output into one flash ROM 11, the output from another flash ROM 11 comes to be fixed to a high level or low level. Consequently, it is possible to efficiently execute the PLP function by preventing the bus fight. Thus, it is possible to shorten the processing time necessary for executing the PLP function, and to increase the data storage amount into the flash ROMs 11.

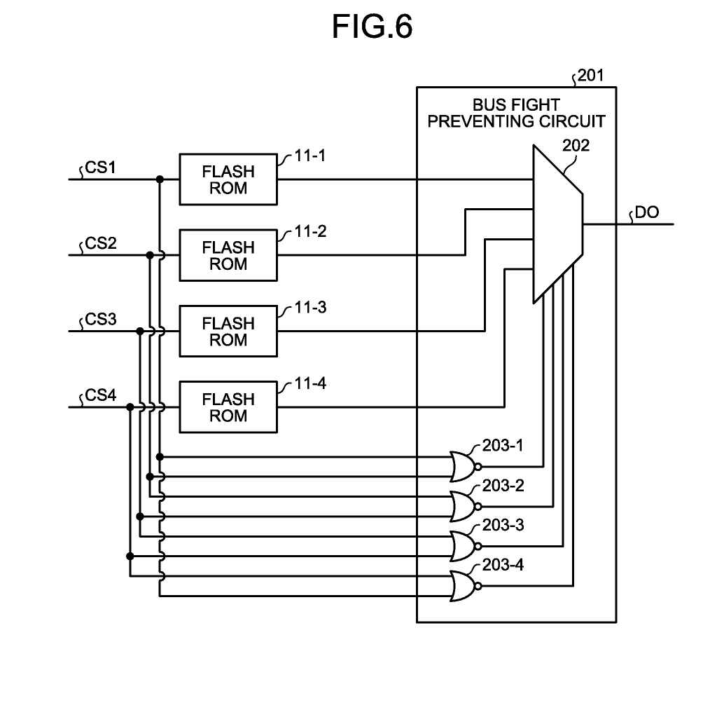

FIG. 6 is a diagram illustrating a configuration example of a bus fight preventing circuit included in the disk device according to the second embodiment. As illustrated in FIG. 6, the bus fight preventing circuit 201 includes a multiplexer 202 and NOR gates 203-1, 203-2, 203-3, and 203-4. The NOR gates 203-1, 203-2, 203-3, and 203-4 output selection control signals into the multiplexer 202, to indicate a flash ROM 11 of the plurality of flash ROMs 11 where its output is to be made effective. In accordance with the selection control signals output from the NOR gates 203-1, 203-2, 203-3, and 203-4, the multiplexer 202 outputs data read from the plurality of flash ROMs 11 selectively into the memory controller 9.

Specifically, the NOR gate 203-1 receives input of chip selection signals via the chip selection signal line CS1 and the chip selection signal line CS2. Here, when the chip selection signals to be input into the chip selection signal line CS1 and the chip selection signal line CS2 are asserted (i.e., when reading of data from the flash ROM 11-1 is to be performed in parallel with writing of data into the flash ROM 11-2), the NOR gate 203-1 outputs a selection control signal indicating selection of data read from the flash ROM 11-1, into the multiplexer 202. Consequently, while writing of data into the flash ROM 11-2 is performed, the data read from the flash ROM 11-1 can be output into the memory controller 9 while preventing a bus fight where the output from the flash ROM 11-1 comes to be fixed to a high level or low level.

Further, the NOR gate 203-2 receives input of chip selection signals via the chip selection signal line CS2 and the chip selection signal line CS3. Here, when the chip selection signals to be input into the chip selection signal line CS2 and the chip selection signal line CS3 are asserted (i.e., when reading of data from the flash ROM 11-2 is to be performed in parallel with writing of data into the flash ROM 11-3), the NOR gate 203-2 outputs a selection control signal indicating selection of data read from the flash ROM 11-2, into the multiplexer 202. Consequently, while writing of data into the flash ROM 11-3 is performed, the data read from the flash ROM 11-2 can be output into the memory controller 9 while preventing a bus fight where the output from the flash ROM 11-2 comes to be fixed to a high level or low level.

Further, the NOR gate 203-3 receives input of chip selection signals via the chip selection signal line CS3 and the chip selection signal line CS4. Here, when the chip selection signals to be input into the chip selection signal line CS3 and the chip selection signal line CS4 are asserted (i.e., when reading of data from the flash ROM 11-3 is to be performed in parallel with writing of data into the flash ROM 11-4), the NOR gate 203-3 outputs a selection control signal indicating selection of data read from the flash ROM 11-3, into the multiplexer 202. Consequently, while writing of data into the flash ROM 11-4 is performed, the data read from the flash ROM 11-3 can be output into the memory controller 9 while preventing a bus fight where the output from the flash ROM 11-3 comes to be fixed to a high level or low level.

Further, the NOR gate 203-4 receives input of chip selection signals via the chip selection signal line CS1 and the chip selection signal line CS4. Here, when the chip selection signals to be input into the chip selection signal line CS1 and the chip selection signal line CS4 are asserted (i.e., when reading of data from the flash ROM 11-4 is to be performed in parallel with writing of data into the flash ROM 11-1), the NOR gate 203-4 outputs a selection control signal indicating selection of data read from the flash ROM 11-4, into the multiplexer 202. Consequently, while writing of data into the flash ROM 11-1 is performed, the data read from the flash ROM 11-4 can be output into the memory controller 9 while preventing a bus fight where the output from the flash ROM 11-4 comes to be fixed to a high level or low level.

As described above, according to second embodiment, the bus fight preventing circuit 201 is included which prevents a bus fight where, while writing of data into one flash ROM is performed, the output from another flash ROM, from which reading of data is performed, comes to be fixed to a high level or low level. As a result, even where the flash ROMs 11 are flash ROMs that can cause a bus fight, it is possible to efficiently execute writing and reading of data into and from the flash ROMs 11 by the PLP function, while preventing the bus fight. Thus, it is possible to shorten the processing time necessary for executing the PLP function, and to increase the data storage amount into the flash ROMs 11.

Several embodiments of the present invention have been described, but these embodiments are presented as examples, and are not intended to limit the scope of the invention. These novel embodiments can be implemented in other various forms, and various omissions, substitutions, and modifications can be performed without departing from the gist of the invention. The embodiments and modifications thereof are included in the scope and gist of the invention, and are included in the invention described in Claims, and a scope equivalent thereto.

What is claimed is:

1. A disk device comprising:
a disk;
a plurality of flash ROMs;
a head configured to perform writing and reading of data into and from the disk;
a cache memory configured to store data under writing into the disk; and
a controller configured to execute an operation when supply of power from an external power supply is interrupted while writing of data into the disk is performed by using power supplied from the external power supply, wherein the operation includes writing data stored in the cache memory into the flash ROMs in order, by means of serial communication, by using power supplied from an auxiliary power supply, in a way of writing data into a first flash ROM of the plurality of flash ROMs, and, in parallel therewith, reading data from a second flash ROM of the plurality of flash ROMs where writing of data is not performed, by means of serial communication.

2. The device according to claim 1, wherein the controller is configured to consecutively output a first command about writing of data into the first flash ROM, and a second command about reading of data from the second flash ROM, by means of serial communication.

3. The device according to claim 1, wherein the controller is configured to read data from the second flash ROM, and to perform verify-read for comparing the data thus read with data written into the second flash ROM.

4. The device according to claim 1, comprising a bus fight preventing circuit configured to prevent generation of a bus fight where, while writing of data into the first flash ROM is performed, output from the second flash ROM comes to be fixed to a high level or low level.

5. The device according to claim 1, wherein the head includes a write head for writing data into the disk and a read head for reading data from the disk.

6. The device according to claim 1, further comprising:
a power supply controller configured to detect that the supply of power from the external power supply is interrupted.

7. The device according to claim 6, wherein the power supply controller supplies a counter electromotive force received from a SPM that rotationally drives the disk, to the controller, as power supplied from the auxiliary power supply.

8. The device according to claim 1, wherein the controller detects an abnormality of writing of the data in the flash ROM, when the data read from the flash ROM differs from the data written into the flash ROM.

9. The device according to claim 4, wherein the bus fight preventing circuit comprising:
a multiplexer configured to output the data read from the flash ROM selectively in the controller according to selection control signals; and
NOR gates configured to output the selection control signals into the multiplexer.

10. A data parallel processing method comprising:
executing an operation when supply of power from an external power supply is interrupted while writing of data into a disk is performed by using power supplied from the external power supply, wherein the operation includes writing data stored in a cache memory and being under writing into the disk, into a plurality of flash ROMs in order, by means of serial communication, by using power supplied from an auxiliary power supply; and
writing data into a first flash ROM of the plurality of flash ROMs, and, in parallel therewith, reading data from a second flash ROM of the plurality of flash ROMs where writing of data is not performed, by means of serial communication.

11. The method according to claim 10, comprising consecutively outputting a first command about writing of data into the first flash ROM, and a second command about reading of data from the second flash ROM, by means of serial communication.

12. The method according to claim 10, comprising: reading data from the second flash ROM; and performing verify-read for comparing the data thus read with data written into the second flash ROM.

13. The method according to claim 10, further comprising detecting that the supply of power from the external power supply is interrupted.

14. The method according to claim 13, further comprising detecting an abnormality of writing of the data in the flash ROM, when the data read from the flash ROM differs from the data written into the flash ROM.
